(19) United States
(12) Patent Application Publication
(10) Pub. No.: US 2026/0271514 A1
(43) Pub. Date: Sep. 10, 2026

(54) LIGHT-EMITTING ELEMENT, DISPLAY DEVICE, NANOPARTICLE DISPERSION, AND LIGHT-EMITTING ELEMENT MANUFACTURING METHOD

(71) Applicant: Sharp Display Technology Corporation, Kameyama City, Mie (JP)

(72) Inventors: Kazuki MARUHASHI, Sakai City, Osaka (JP); YOSHIHIRO UETA, Sakai City, Osaka (JP); TAKAYUKI NAKA, Sakai City, Osaka (JP)

(21) Appl. No.: 19/122,878

(22) PCT Filed: Oct. 28, 2022
(86) PCT No.: PCT/JP2022/040352

§ 371 Date: Apr. 21, 2025

(51) Int. Cl. H10K 50/854; H10K 50/15; H10K 102/00

(52) U.S. Cl. CPC H10K 50/854; H10K 50/15; H10K 2102/351

(57) ABSTRACT

A light-emitting element includes: an anode and a cathode; a light-emitting layer positioned between the anode and the cathode; and a light-scattering layer positioned between the light-emitting layer and the anode and containing metal oxide that transports holes.

### TECHNICAL FIELD

The present disclosure relates to a light-emitting element, a display device, a nanoparticle dispersion, and a light-emitting element manufacturing method.

### BACKGROUND ART

As a known light-emitting element, a quantum-dot light-emitting diode including a hole injection layer containing nickel oxide (NiO) is known in the art.

### CITATION LIST

### Patent Literature

[Patent Document 1] United States Patent Application Publication No. 2021/0091325
[Patent Document 2] Chinese Patent Application Publication No. 105895829

### SUMMARY

### Technical Problem

The known light-emitting element has a problem of low light extraction efficiency.

### Solution to Problem

A light-emitting element according to an aspect of the present disclosure includes: an anode and a cathode; a light-emitting layer positioned between the anode and the cathode; and a light-scattering layer positioned between the light-emitting layer and the anode and containing metal oxide that transports holes.

### Advantageous Effect of Disclosure

According to an aspect of the present disclosure, a light-emitting element can release light efficiently.

### BRIEF DESCRIPTION OF DRAWINGS

FIG. 1 is a schematic view illustrating an exemplary configuration of a display device according to an embodiment.

FIG. 2 is a cross-sectional view illustrating an exemplary configuration of the display device according to the embodiment.

FIG. 3 is a cross-sectional view illustrating an exemplary configuration of a light-emitting element according to the embodiment.

FIG. 4 is a cross-sectional view illustrating an exemplary configuration of the light-emitting element according to the embodiment.

FIG. 5 is a cross-sectional view illustrating an exemplary configuration of the display device according to the embodiment.

FIG. 6 is a schematic cross-sectional view illustrating an exemplary configuration of the light-emitting element according to the embodiment.

FIG. 7 is a graph illustrating a relationship between a slope of an upper surface of a light-scattering layer and light extraction efficiency.

FIG. 8 is a cross-sectional view illustrating another example of the light-emitting element according to the embodiment.

FIG. 9A is a conceptional diagram of a light-scattering layer.

FIG. 9B is a conceptional diagram of a light-scattering layer thicker than the light-scattering layer in FIG. 9A.

FIG. 9C is a conceptional diagram of a light-scattering layer thicker than the light-scattering layer in FIG. 9B.

FIG. 10 is a cross-sectional view illustrating another exemplary configuration of the light-emitting element according to the embodiment.

FIG. 11 is a flowchart showing a method for manufacturing the light-emitting element according to this embodiment.

FIG. 12 is a flowchart showing a method for forming the light-scattering layer according to this embodiment.

FIG. 13 is a cross-sectional SEM image of an example of a light-emitting element.

FIG. 14 is a cross-sectional SEM image of another example of the light-emitting element.

FIG. 15 is a cross-sectional SEM image of another example of the light-emitting element.

FIG. 16 is a STEM image of the light-emitting element in FIG. 13.

FIG. 17 is a STEM image of the light-emitting element in FIG. 14.

FIG. 18 is a STEM image of the light-emitting element in FIG. 15.

FIG. 19 is a graph illustrating a relationship between the number of applications and a thickness in forming the light-scattering layer.

FIG. 20A is a graph illustrating voltage to current-density characteristics of the light-emitting element observed when the thickness (the number of applications) of the light-scattering layer varies.

FIG. 20B is a graph illustrating voltage to current-density characteristics of the light-emitting element observed when the thickness (the number of applications) of the light-scattering layer varies.

FIG. 21A is a graph illustrating voltage to luminance characteristics of the light-emitting element observed when the thickness (the number of applications) of the light-scattering layer varies.

FIG. 21B is a graph illustrating voltage to luminance characteristics of the light-emitting element observed when the thickness (the number of applications) of the light-scattering layer varies.

FIG. 22A is a graph illustrating current-density to EQE characteristics of the light-emitting element observed when the thickness (the number of applications) of the light-scattering layer varies.

FIG. 22B is a graph illustrating current-density to EQE characteristics of the light-emitting element observed when the thickness (the number of applications) of the light-scattering layer varies.

FIG. 23A is a graph illustrating current-density to luminance characteristics of the light-emitting element observed when the thickness (the number of applications) of the light-scattering layer varies.

FIG. 23B is a graph illustrating current-density to luminance characteristics of the light-emitting element observed when the thickness (the number of applications) of the light-scattering layer varies.

FIG. 24 is a graph illustrating time-related variations in relative luminance of the light-emitting element observed when the thickness (the number of applications) of the light-scattering layer varies.

FIG. 25 is a graph illustrating time-related variations in relative luminance of the light-emitting element observed when a solvent of a nanoparticle dispersion is changed.

### DESCRIPTION OF EMBODIMENT

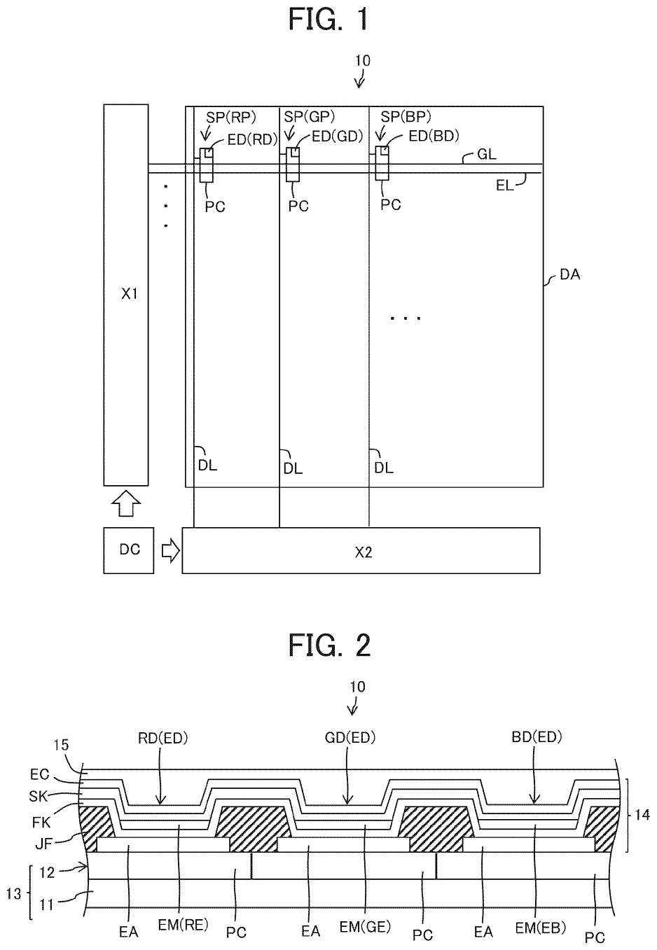

FIG. 1 is a schematic view illustrating an exemplary configuration of a display device according to an embodiment. FIG. 2 is a cross-sectional view illustrating an exemplary configuration of the display device according to the embodiment. As illustrated in FIG. 1, a display device 10 includes: a display unit DA including a plurality of subpixels SP; a first driver X1 and a second driver X2 that drive the plurality of subpixels SP; and a display control unit DC that controls the first driver X1 and the second driver X2. Each of the subpixels SP includes: a light-emitting element ED; and a pixel circuit PC connecting to the light-emitting element ED. The pixel circuit PC may be connected to a scan signal line GL, a data signal line, and a light-emission control line DL. The scan signal line GL and the light-emission control line EL may be connected to the first driver X1, and the data signal line DL may be connected to the second driver X2.

The display device 10 may include: a pixel circuit substrate 13 including a substrate 11 and a pixel circuit layer 12; a light-emitting-element layer 14; and a sealing layer 15. The substrate 11 may be, for example, a glass substrate and a resin substrate. The substrate 11 may be flexible. The pixel circuit layer 12 includes, for example, a plurality of the pixel circuits PC arranged in a matrix. The pixel circuit PC may include: a pixel capacitor in which a grayscale signal is written; a transistor that controls a current value of the light-emitting element ED in accordance with the grayscale signal; a transistor connected to the scan signal line GL and the data signal line DL; and a transistor connected to the light-emission control line EL.

As illustrated in FIG. 2, the light-emitting-element layer 14 may include: an anode EA; an edge cover film JF covering an edge of the anode EA; a first functional layer FK; a light-emitting layer EM; a second functional layer SK; and a cathode EC, all of which are sequentially stacked from toward the pixel circuit substrate 13. The first functional layer FK is capable of transporting holes, and the second functional layer SK is capable of transporting electrons. The light-emitting-element layer 14 may include: a light-emitting element RD (ED) including a light-emitting-element layer RE (EM) that emits a red light; a light-emitting element GD (ED) including a light-emitting layer GE (EM) that emits a green light; and a light-emitting element BD (ED) including a light-emitting layer BE (EM) that emits a blue light. The sealing layer 15 includes an inorganic insulating film such as a silicon nitride film or a silicon oxide film, and prevents foreign substances (e.g., water and oxygen) from entering the light-emitting element layer 14.

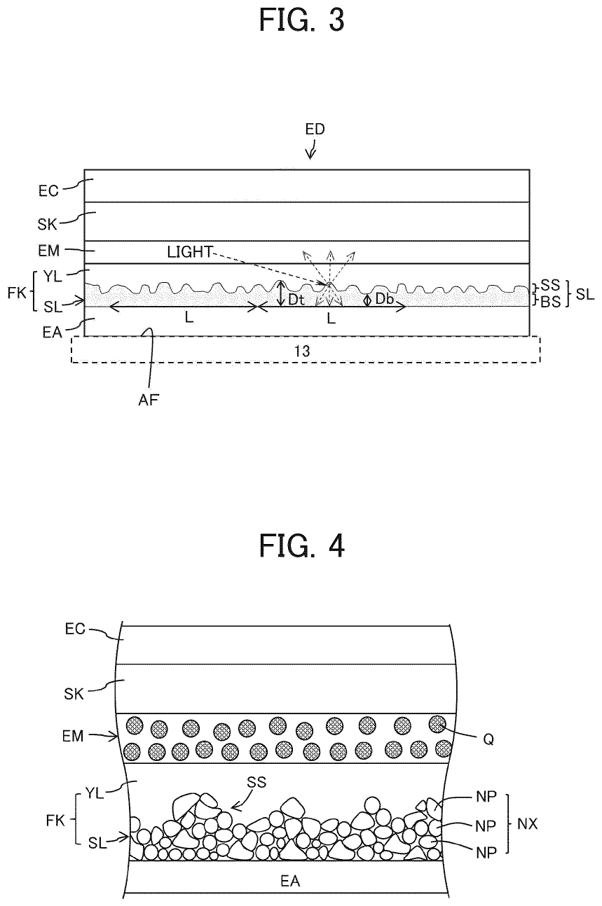

FIG. 3 is a cross-sectional view illustrating an exemplary configuration of the light-emitting element according to the embodiment. As illustrated in FIG. 3, the light-emitting element ED includes: the anode EA and the cathode EC; the light-emitting layer EM positioned between the anode EA and the cathode EC; and a light-scattering layer SL positioned between the light-emitting layer EM and the anode EA and containing metal oxide that transports holes. In the light-emitting element ED, the light-scattering layer SL transports the holes, which are supplied from the anode EA, toward the light-emitting layer EM. Simultaneously, the light-scattering layer SL has an upper surface that scatters light (incident light) incident at a small angle with respect to a surface (e.g., a substrate surface AF) perpendicular to a thickness direction of the light-emitting element ED, so that the scattering light scatters at a large angle with respect to the substrate surface. Thanks to such a feature, the light-emitting element ED releases light more efficiently. The upper surface of the light-scattering layer may have asperities to cause Rayleigh scattering (e.g., Rayleigh scattering of visible light). The asperities of the upper surface may cause irregular reflection of light including scattering and reflection of light.

If the light-emitting element ED is a top-emission light-emitting element (i.e., the light is released across from the pixel circuit substrate 13), the anode EA may be a light-reflective electrode and the cathode EC may be a light-transparent electrode. The scattering light traveling from the light-scattering layer SL downwards is reflected on the anode EA. If the light-emitting element ED is a bottom-emission light-emitting element (i.e., the light is released toward the pixel circuit substrate 13), the anode EA may be a light-transparent electrode and the cathode EC may be a light-reflective electrode. The scattering light traveling from the light-scattering layer SL upwards is reflected on the cathode EC. When the anode EA is a light-reflective electrode, the anode EA may be, for example, a multilayer stack including: a silver (Ag) film or an aluminum (Al) film downwards; and an indium tin oxide (ITO) film upwards. When the anode EA is a light-transparent electrode, the anode EA can be, for example, an ITO film.

In view of achieving both the hole transport function (reliability) and the light scattering function of the light-scattering layer SL, the light-scattering layer SL has an upper surface roughness of preferably 5 [nm] to 70 [nm]. The upper surface roughness may be the roughness of a surface provided to the light-scattering layer SL and away from the pixel circuit substrate 13.

The upper surface roughness of the light-scattering layer SL is defined as a difference (Dt−Db) between a maximum thickness Dt and a minimum thickness Db from observation of a cross-section in parallel with a thickness direction of the light-scattering layer. The observation field may extend over an entire width of the light-scattering layer SL, or may be any of a plurality of regions (wherein a width of each region is defined as a unit length L) into which the entire width of the light-scattering layer SL is divided. In such a case, a plurality of the upper surface roughnesses corresponding to the plurality of regions may have an average value of 5 [nm] to 70 [nm]. The unit length Lis, for example, 500 [nm], and a value of which may depend on the entire width of the light-scattering layer SL.

The upper surface roughness of the light-scattering layer SL is observed preferably in a cross-sectional view of a cross-sectional SEM image. As will be described later, the upper surface roughness can be observed in an image of a STEM image in addition to the cross-sectional SEM image. However, as to the STEM image, it might be difficult to identify the upper surface roughness since depth information is also observed in the STEM image. Hence, in observing the upper surface roughness in the cross-section, the cross-sectional SEM image is used in preference to the STEM image.

The light-scattering layer SL may include: a base portion BS positioned toward the anode EA; and a light-scattering portion SS (surface asperities) positioned toward the light-emitting layer EM. The base portion BS may have a thickness of 45 [%] or more of the upper surface roughness of the light-scattering layer SL. The thickness of the base portion BS can be defined as the minimum thickness Db of the light-scattering layer SL in the unit length L. The light-scattering portion SS (surface asperities) may have a non-uniform shape (a random shape) in the surface. The surface asperities on the upper surface of the light-scattering layer SL may form the light-scattering portion SS. The upper surface roughness may be a maximum difference in height between the upper surface asperities.

The light-scattering layer SL contains carbon atoms of 0 [at %] to 5 [at %]. The light-scattering layer SL may omit organic ligands. That is, in the light-scattering layer SL, carbon of organic origin is not desirably left. Such a feature keeps an organic substance from blocking conduction of the holes in the light-scattering layer SL, and improves the hole transport function. As a result, the holes are injected more efficiently into the light-emitting layer EM, thereby improving a carrier balance of the light-emitting element that typically contains excessive electrons. The feature also reduces a voltage to be applied to the light-emitting element ED. Furthermore, the feature can eliminate a phenomenon of an increase in solubility to an organic solvent because of the organic ligands. Hence, in a process of forming an upper layer (e.g., application of a solution containing an organic solvent), the feature can solve a problem of dissolving (reducing) the light-scattering layer SL.

The light-emitting element ED may include a hole transport layer YL positioned between the light-scattering layer SL and the light-emitting layer EM and containing an organic material. A valence band maximum (VBM) of the hole transport layer YL is set to a level between a VBM of the light-scattering layer SL and a VBM of the light-emitting layer EM. Such a feature reduces a barrier to injection of the holes and enhances the hole transport function of the first functional layer FK. Note that the VBM can be also referred to as a highest occupied molecular orbital (HOMO). Furthermore, the hole transport layer YL is formed by application, such that the upper surface roughness of the hole transport layer YL can be smaller than the upper surface roughness of the light-scattering layer SL. The hole transport layer YL keeps the light-emitting layer EM away from defects contained in the metal oxide of the light-scattering layer SL and a dipole, thereby successfully reducing deactivation of excitons generated by recombination.

The hole transport layer YL may be lower in refractive index than the light-scattering layer SL. Such a feature increases an effective refractive index acting on the light incident from the light-emitting layer EM onto the light-scattering layer SL. As to Rayleigh scattering, the greater the refractive index of the scattering center is, the stronger the scattering light is. Hence, the light can be released more efficiently. A difference in refractive index between the light-scattering layer SL and the hole transport layer YL in contact with the light-scattering layer SL toward the cathode EC may be 0.5 or more. The light-scattering layer SL containing, for example, a bulk material has a refractive index ns of typically 2.0 or more. The hole transport layer YL containing an organic compound has a refractive index ny of typically less than 1.5 (e.g., poly-TPD has a refractive index of 1.46) so that a relationship of ns−ny≥0.5 holds.

The hole transport layer YL may have a lower surface shaped in conformity with the upper surface of the light-scattering layer SL. The hole transport layer YL has a thickness greater than the upper surface roughness of the light-scattering layer SL. Thanks to such a feature, the hole transport layer YL can fill the asperities on the surface of the light-scattering layer SL so that the light-emitting layer EM is formed flat on the hole transport layer YL. Examples of a material (an organic material) of the hole transport layer YL include TFB, PVK, poly-TPD, TPD, TAPC, TcTa, α-NPD, CBP, and m-MTDATA.

The upper surface roughness of the light-scattering layer SL may be 45 [nm] or less. Thanks to such a feature, a blue light having a wavelength of 450 nm or less can be efficiently Rayleigh-scattered. The upper surface roughness of the light-scattering layer SL may be 30 [nm] or less. Thanks to such a feature, the hole transport layer YL is suitable when the hole transport layer YL is 30 [nm] or less. The upper surface roughness may be 15 [nm] or less. Thanks to such a feature, a sufficiently great roughness can be provided to cause irregular reflection of light in a great degree so that the light can be released more efficiently.

The light-scattering layer SL may contain at least one of nickel oxide, copper oxide, vanadium oxide, molybdenum oxide, or tungsten oxide, each of which serves as a metal oxide capable of transporting holes. The copper oxide may be either Cu₂O (cuprous oxide) or CuO (cupric oxide). The light-scattering layer SL may have a thickness of 47 [nm] or more. The thickness of the light-scattering layer SL may be, as described above, an average value of the maximum thicknesses Dt per unit length (L).

FIG. 4 is a cross-sectional view illustrating an exemplary configuration of the light-emitting element according to the embodiment. The light-scattering layer SL may have a polycrystalline structure. The light-scattering layer SL may have a plurality of nanoparticles NP. Each of the nanoparticles NP may be a metal oxide particle having a particle size (an outer diameter) of 1.0 [nm] to 100 [nm]. If the nanoparticle NP is not spherical, the nanoparticle NP may be, for example, isometrically transformed into a sphere, and the diameter of the sphere may be the particle size. For example, when a cross-section of the nanoparticle NP is observed, a circle is obtained to have an area equivalent to the area of the cross-section of the nanoparticle NP. A value of the diameter of the circle may be determined to be the particle size of the nanoparticle NP. A shape of the nanoparticle NP shall not be limited to a spherical three-dimensional shape (with a circular cross-section). For example, the quantum dot may have a polygonal cross-section, a bar-like three-dimensional shape, a branch-like three-dimensional shape, or a three-dimensional shape having asperities on the surface. Alternatively, the quantum dot may have a combination of those shapes.

The nanoparticles NP may contain one or more of nickel oxide, copper oxide, vanadium oxide, molybdenum oxide and tungsten oxide. The nanoparticles NP may be formed of nickel oxide. Transition metal oxides typically have composition deviation, and the nickel oxide can be represented by, for example, NiOₓ (x=0.5 to 1.5). In the light-scattering layer SL, the nanoparticles NP may have a particle size (e.g., a median diameter) of 4.0 [nm] or more. In this case, even if no organic ligands are coordinated, the nanoparticles NP are more likely to disperse, and less likely to agglomerate together, in the solution. When the particle size of the nanoparticles NP is checked, the solution is applied and a cross-sectional image of the solution is obtained with, for example, a transmission electron microscope (TEM), a scanning transmission electron microscope (STEM), and a scanning electron microscope (SEM). The image is observed, so that the particle size of the nanoparticles NP can be checked. Specifically, a particle size distribution is calculated for all the nanoparticles NP in sight (e.g., 10 to 100 nanoparticles NP). For example, if the particle size at which the culminated number of nanoparticles NP reaches 50% in the particle size distribution is 4 nm or more (D50: the median diameter), the particle size of the nanoparticles NP in a nanoparticle group NX is determined to be 4 nm or more. It is more preferable that the particle size (D10) at which the cumulative number reaches 10% in the particle diameter distribution (D10) is 4 nm or more (i.e., 90% of the nanoparticles have a particle size of 4 nm or more). It is still more preferable that all the particles have a particle size of 4 nm or more. The particle size of the nanoparticles NP is represented preferably by median diameter, by mode diameter next to the median diameter, and by average diameter next to the mode diameter.

If the light-scattering layer SL is a nickel oxide nanoparticle layer containing a nickel oxide nanoparticle group NX, the upper surface roughness of the light-scattering layer SL may be larger than the particle size of the nanoparticles NP in the nanoparticle group NX, and may be smaller than 1/10 of an emission peak wavelength of the light-emitting layer EM. Such a feature makes it possible to enhance light extraction efficiency by Rayleigh scattering, while maintaining the function to transport (to inject) the holes. The upper surface roughness may be either a difference between the maximum thickness and the minimum thickness, or an arithmetic average roughness Ra, in the cross-section of the light-scattering layer. The particle size of the nanoparticles NP is represented preferably by median diameter. Alternatively, the particle size may be represented either by mode diameter or by average diameter. As illustrated in FIG. 4, the hole transport layer YL containing an organic material may be provided between the light-scattering layer SL containing the nickel oxide nanoparticle group NX (a nickel oxide nanoparticle layer) and the light-emitting layer EM. Here, the hole transport layer YL is smaller in upper surface roughness than the nickel oxide nanoparticle layer (the light-scattering layer SL). In other words, the hole transport layer YL can flatten the surface asperities (the light-scattering portion SS) formed of the nickel oxide nanoparticles aggregate on the surface.

The light-emitting layer EM may contain quantum dots Q. Each of the quantum dots Q may be a particle having a particle size (an outer diameter) of 1.0 [nm] to 100 [nm]. The quantum dot Q may be spherical or non-spherical. The shape of the quantum dot Q shall not be limited to a spherical three-dimensional shape (with a circular cross-section) as long as the particle size is within the above range. For example, the quantum dot Q may have a polygonal cross-section, a bar-like three-dimensional shape, a branch-like three-dimensional shape, or a three-dimensional shape having asperities on the surface. Alternatively, the quantum dot may have a combination of those shapes. The quantum dots Q may be formed of a semiconductor material. The semiconductor material may have a certain bandgap, and may be a material that produces electroluminescence. The electroluminescence may have a wavelength region of any of a red gamut, a green gamut, and a blue gamut.

The quantum dots Q may contain at least: crystals of II-VI group semiconductors such as MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, HgTe; crystals of III-V group semiconductors such as GaAs, GaP, InN, InAs, InP, InSb; or crystals of IV group semiconductors such as Si and Ge. The light-emitting layer EM may contain an inorganic matrix material (e.g., an inorganic compound larger in bandgap than the quantum dots Q) filling space between the plurality of quantum dots Q. The inorganic matrix material may contain at least one of zinc sulfide or magnesium sulfide.

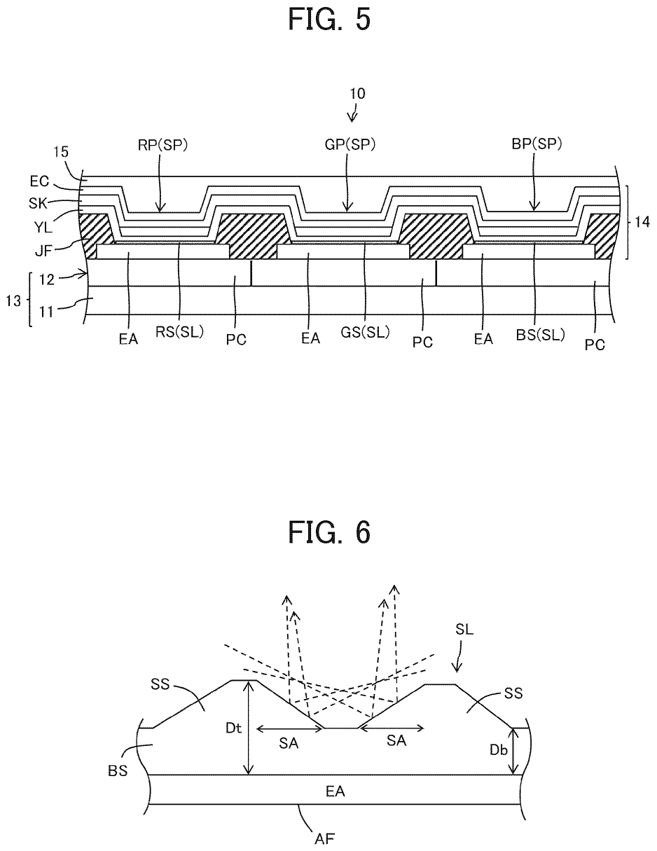

FIG. 5 is a cross-sectional view illustrating an exemplary configuration of the display device according to the embodiment. As illustrated in FIG. 1 and FIG. 5, the display device 10 may include: a first subpixel RP that emits a red light; a second subpixel GP that emits a green light; and a third subpixel BP that emits a blue light. The first subpixel RP may include the light-emitting element RD (ED). The second subpixel GP may include the light-emitting element GD (ED). The third subpixel BP may include the light-emitting element BD (ED). In FIG. 5, a relationship of the upper surface roughness of the light-scattering layer RS (SL) in the first subpixel RP>the upper surface roughness of the light-scattering layer GS (SL) in the second subpixel GP>the upper surface roughness of the light-scattering layer BS (SL) in the third subpixel BP may hold. Such a feature can optimize intensity of Rayleigh scattering for each of the subpixels (colors), so that the light can be released more efficiently.

FIG. 6 is a schematic cross-sectional view illustrating an exemplary configuration of the light-emitting element according to the embodiment. The upper surface (the light-scattering portion SS) of the light-scattering layer SL may be provided with a region SA having a slope forming an angle of 16 degrees or more and 43 degrees or less with respect to a plane in parallel with the anode EA. In this case, light at a small angle with respect to the substrate surface can be reflected to form a large angle with respect to the substrate surface. Thanks to such a feature, the light-emitting element ED releases light more efficiently.

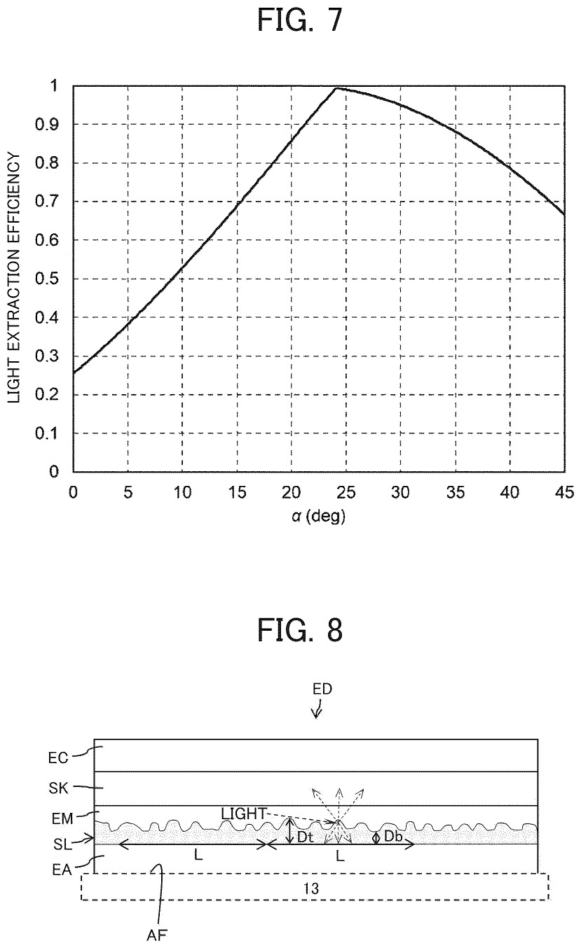

In allowing for a loss caused by total reflection on the glass/air interface, if the angle of the slope is set within the range of 16 degrees or more and 43 degrees or less, the efficiency in releasing the light emitted downwards (in a direction from the light-emitting layer EM toward the anode EA) can be increased by 70% or more (in a theoretical value). FIG. 7 is a graph illustrating a relationship between the slope of the upper surface of the light-scattering layer and releasing efficiency. Typically, the light extraction efficiency γ, which is observed when light travels from a first medium (having a refractive index n₁) to a second medium (having a refractive index n₂<n₁), can be calculated as shown in Equation 1 below. Note that the light is emitted in all directions in equal amount. Wherein, the denominator 2× is the total sum of the solid angles of the hemispherical surface, θ_{C} is a critical angle, and a relationship of sin θ_{C}=n₂/n₁ holds. Hence, the light extraction efficiency γ is represented by Equation 2 below. For example, if the first medium is glass and the second medium is air, relationships of n₂≈1.5, θ_{C}≈41.8 deg, and γ≈0.25 hold.

$$\begin{matrix}[ Math . 1 ] & \\ γ = \frac{1}{2 π} {\int }_{φ = 0}^{φ = 2 π} d φ {\int }_{θ = 0}^{θ = {θ}_{C}} sin θ d θ & Equation 1\end{matrix}$$

$$\begin{matrix}[ Math . 2 ] & \\ γ = 1 - cos {θ}_{C} = 1 - \sqrt{1 - {( \frac{{n}_{2}}{{n}_{1}} )}^{2}} & Equation 2\end{matrix}$$

Studied here is light extraction efficiency emitted in a direction opposite to the releasing direction (i.e., emitted downwards). It is assumed that the light is reflected on an interface and directed in the releasing direction (i.e., directed upwards), and that the interface is inclined at an angle α from the horizontal plane. Note that the angle α is 45° or less. When the light reflects, the incident angle (the inclination of the light ray from the normal line of the releasing surface) varies between θ and abs(θ−2α). According to the variation, the efficiency in releasing the light traveling downwards is expressed by Equation 3 below.

$$\begin{matrix}[ Math . 3 ] & \\ γ = \frac{1}{2 π} {\int }_{φ = 0}^{φ = 2 π} d φ {\int }_{θ = L}^{θ = R} sin θ d θ = cos R - cos L & Equation 3\end{matrix}$$

Note that relationships of R=min(θ_{C}+2α, π/2) and L=max(2α−θ_{C}, 0) hold. As a result, the overall extraction efficiency of the light travelling downwards is represented as shown in FIG. 7. If the angle of the slope of a surface (the upper surface) of the light-scattering layer SL toward the light-emitting layer EM is set within a range of 16 degrees or more and 43 degrees or less, the extraction efficiency of the light emitted downwards can be increased by 70% or more.

FIG. 8 is a cross-sectional view illustrating another example of the light-emitting element according to the embodiment. As illustrated in FIG. 8, the light-emitting layer EM may be formed in contact with the light-scattering layer SL. In this case, an interface is formed between the light-scattering layer SL and the light-emitting layer EM. The light-emitting layer EM has a thickness greater than the upper surface roughness of the light-scattering layer SL. The upper surface roughness of the light-scattering layer SL may be 15 [nm] or less. This is suitable in a case where the thickness of the light-emitting layer EM is 15 [nm] or less. The light-scattering layer SL may be greater in refractive index than the light-emitting layer EM. A difference in refractive index between the light-scattering layer SL and the light-emitting layer EM in contact with the light-scattering layer SL toward the cathode EC may be 0.5 or more.

As illustrated in FIG. 3, FIG. 4 and FIG. 8, the anode EA, the light-scattering layer SL, and the light-emitting layer EM are formed in the stated order above the pixel circuit substrate 13. Such a structure (the non-inverted structure), which has the light-scattering layer SL formed by a predetermined application technique, is beneficial in: forming a desired roughness (i.e., a roughness capable of both scattering light and transporting holes) on the upper surface of the light-scattering layer SL; and keeping heat, which is generated in firing the light-scattering layer SL, from affecting the light-emitting layer EM.

In the light-emitting element ED of FIG. 4, the light-scattering layer SL has the upper surface whose roughness is sufficiently large to scatter on the upper surface light at a small angle with respect to the substrate surface, but is not excessively large so as not to exhibit significant current concentration. The light-scattering layer SL is formed of nickel oxide nanoparticles NP. Specifically, the light-scattering layer SL has an upper surface roughness of 5 [nm] to 70 [nm]. If the thickness of the light-scattering layer SL increases, a rate of variation in the thickness is small even though the light-scattering layer SL has the upper surface roughness. Such a feature can reduce influence on characteristics such as current concentration.

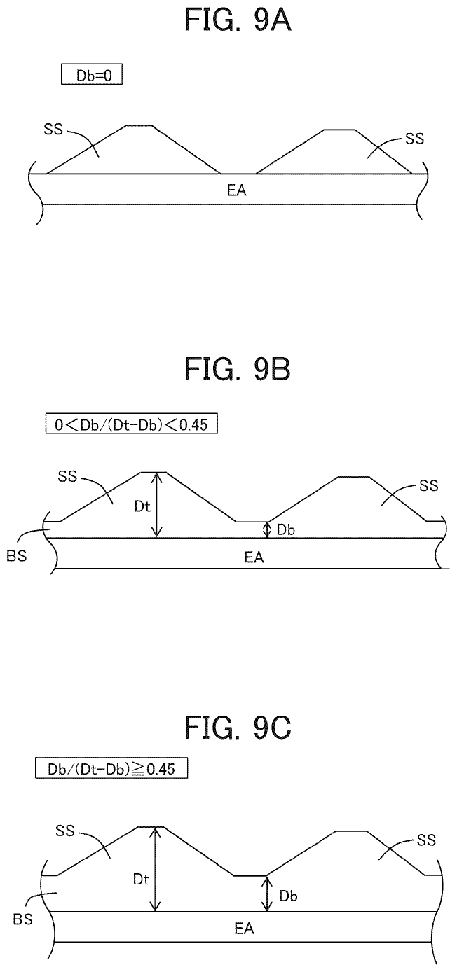

FIG. 9A to FIG. 9C are conceptional diagrams of light-scattering layers in different thicknesses. A light-scattering layer SL in FIG. 9A has a zero-thickness region. In other words, the light-scattering layer SL of FIG. 9(A) has no base portion. In the zero-thickness region, the holes are less likely to be injected. This might reduce capability in transporting the holes. In FIG. 9(B), there is no zero-thickness region; however, the rate of variation in the thickness is large. This might cause current concentration in a region having a small thickness. In FIG. 9(C), the thickness Db of the base portion is appropriate, and the rate of variation in the thickness is sufficiently small. Hence, the current concentration is less likely to occur, and the light-scattering layer SL of FIG. 9(C) contributes to excellent EQE, uniform emission of light, and high reliability.

Typically, an excessively thick hole injection layer raises a drive voltage and adversely affects the EQE. However, the light-scattering layer SL formed of nickel oxide nanoparticles NP produces a phenomenon in which the drive voltage would rather fall when the light-scattering layer SL is thick. This is probably because, as illustrated in FIG. 9(A), the thin light-scattering layer SL has a region in which no nickel oxide nanoparticles NP are found, and the region inhibits injection of the holes. However, when the light-scattering layer SL becomes thick as illustrated in FIG. 9(B) and FIG. 9(C), the region with no nanoparticles NP disappears, and the injection of the holes is increased. In the configuration of FIG. 9(C) that achieves excellent EQE, a relationship of Db/(Dt−Db)≥0.45 may hold. Note that Db/(Dt−Db) is a ratio of the thickness of the base portion BS to the upper surface roughness.

This embodiment optimizes the upper surface roughness and the thickness of the light-scattering layer SL, so as to successfully minimize adverse effects on the reliability and the EQE and to simultaneously enhance the light extraction efficiency. The light-scattering layer SL is originally a metal oxide layer required to drive a light-emitting element and capable of transporting the holes, and thus is preferable in view of costs. As will be described later, it has been clearly found that a nanoparticle dispersion, which contains nickel oxide nanoparticles NP and a specific solvent, is applied multiple times to form the light-scattering layer SL so that the thickness and the upper surface roughness of the light-scattering layer SL can be optimized. Specifically, the light-scattering layer SL has an upper surface roughness of 5 [nm] to 70 [nm] and a thickness of 47 nm.

No organic ligands are coordinated to the nickel oxide nanoparticles NP of the light-scattering layer SL. Such a feature enhances the hole injection capability of, and improves the carrier balance of, the light-scattering layer SL. No organic ligands are coordinated to the nanoparticles NP, thereby reducing a rise of the drive voltage associated with the light-scattering layer SL formed thick.

When a nanoparticle layer in which organic ligands are coordinated is used as the hole injection layer, the nanoparticle layer becomes more soluble in the organic solvent. Hence, when the hole transport layer and the light-emitting layer are applied above, the hole injection layer (the nanoparticle layer) may reduce in thickness. In particular, if the hole injection layer includes an upper surface roughness, a thin portion of the upper surface roughness is further reduced, which could cause current concentration and the resulting decrease in the EQE. In the structure of FIG. 4, such a problem can be avoided because no organic ligands are coordinated to the nanoparticles NP of the light-scattering layer SL such that the light-scattering layer SL is less likely to be dissolved in the organic solvent.

Between the light-scattering layer SL, which contains the nickel oxide nanoparticles NP, and the light-emitting layer EM, the hole transport layer YL containing an organic material is formed. The hole transport layer YL is smaller in upper surface roughness than the light-scattering layer SL containing the nickel oxide nanoparticles NP. Hence, when the hole transport layer YL is applied, the lower surface roughness of the light-emitting layer EM (the quantum-dot layer) is smaller than the upper surface roughness of the light-scattering layer SL. Such a feature can minimize decreases in reliability caused by current concentration and in the EQE caused by an increase in reactive current. The hole transport layer YL is formed of an organic material, and is typically lower in refractive index than the light-scattering layer SL containing nickel oxide nanoparticles NP. Such a feature can enhance intensity of scattering light scattered by Rayleigh scattering.

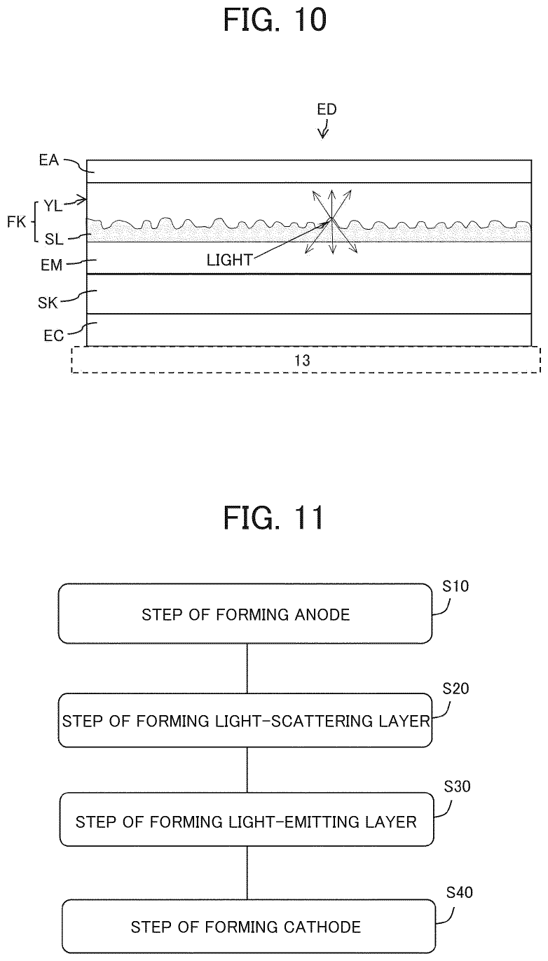

FIG. 10 is a cross-sectional view illustrating another exemplary configuration of the light-emitting element according to the embodiment. The light-emitting element ED of FIG. 10 may contain: the cathode EC; the second functional layer (an electron transport layer) SK; the light-emitting layer EM; the first functional layer FK; and the anode EA, all of which are sequentially provided from toward the pixel circuit substrate 13. The first functional layer FK includes: the light-scattering layer SL containing a metal oxide capable of transporting the holes; and the hole transport layer YL positioned above the light-scattering layer SL. In the light-emitting element ED, the light-scattering layer SL transports the holes, which are supplied from the anode EA, toward the light-emitting layer EM. Simultaneously, the light-scattering layer SL has an upper surface that scatters light (incident light) incident at a small angle with respect to a surface (e.g., a substrate surface AF) perpendicular to a thickness direction of the light-emitting element, so that the scattering light scatters at a large angle with respect to the substrate surface AF. Thanks to such a feature, the light-emitting element ED releases light more efficiently.

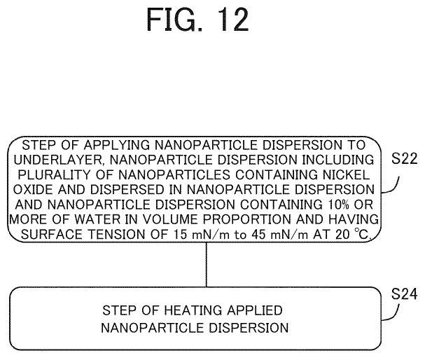

FIG. 11 is a flowchart showing a method for manufacturing the light-emitting element according to this embodiment. FIG. 12 is a flowchart showing a method for forming the light-scattering layer according to this embodiment. As shown in FIG. 11, the method for manufacturing the light-emitting element according to this embodiment includes: a step of forming the anode (S10); a step of forming the light-scattering layer (S20); a step of forming the light-emitting layer (S30); and a step of forming the cathode (S40). As shown in FIG. 12, the step of forming the light-scattering layer (S20) includes: a step (S22) of applying a nanoparticle dispersion to an underlayer (e.g., the anode); and a step (S24) of heating the applied nanoparticle dispersion. Here, the nanoparticle dispersion includes a plurality of nanoparticles containing nickel oxide and dispersed in the nanoparticle dispersion. The nanoparticle dispersion contains 10% or more of water in volume proportion, and has a surface tension of 15 mN/m to 45 mN/m at 20° C. After the nanoparticle dispersion is applied, the step of heating the applied nanoparticle dispersion may be repeated multiple times. The heating temperature is preferably 100° C. or higher, and more preferably 150° C. or higher. Such a feature can reduce the amount of the disperse solvent and the inorganic ligands contained in the nanoparticle dispersion and left in the light-scattering layer, and improve the hole transport capability of the light-scattering layer. In addition, when Step S22 and Step S24 are repeated multiple times, at second and subsequent Steps S22 (i.e., the steps of applying the nanoparticle dispersion to the nanoparticle layer), the lower layer (i.e., the nanoparticle layer) is less likely to be dissolved, thereby successfully keeping the lower layer from reducing in thickness. The nanoparticle dispersion may contain: nickel oxide nanoparticles; water (H₂O); and at least one of 2-methoxyethanol, 1,4-dioxane, 2-butanol, 1-butanol, pyridine, acetic acid, or acetylacetone. The underlayer to which the nanoparticle dispersion is applied shall not be limited to the anode. The underlayer may be, for example, the hole injection layer.

### EXAMPLES

### Preparing Nickel Oxide Nanoparticles

A nickel nitrate hexahydrate (Ni(NO₃)₂·6H₂O) of 0.05 mmol and a pure water of 20 mL were placed in a vial container and stirred together. After that, an aqueous sodium hydroxide of 10 mol/L was added to reach a pH 9 or higher. Hence, a green precipitate was obtained. At a rinse step, pure water was added to the green precipitate, and the mixture was centrifuged and the supernatant fluid was removed. The rinse step was repeated three times, and, after that, the mixture underwent a drying step. Hence, a green powder was obtained. This green powder was fired at 270° C. for two hours. Hence, black nickel oxide nanoparticles (powder) were obtained.

The aqueous sodium hydroxide is added to the solution so that the pH of the solution varies. Hence, the particle size of the nickel oxide nanoparticles can be controlled. Nickel oxide nanoparticles were prepared at several pHs, and, for each of the pHs, the nickel oxide nanoparticles were measured by the X-ray diffraction. Hence, a crystallite size D (nm) was calculated from Scherrer's equation as follows.

D (nm)=0.89λ(nm)/B (deg)cos θ.

Note that λ(nm) represents a wavelength of an X-ray. For this measurement, a Cu Kα ray was used wherein λ(nm)=0.154. B (deg) represents an X-ray diffraction peak width, and 0 represents a diffraction angle.

Furthermore, nickel oxide nanoparticles at each crystallite size were dispersed in an aqueous solvent, and a test was conducted to find out whether the solution would pass through a 0.45-μm filter. Furthermore, the passing solution was measured for particle size distribution. Hence, a median diameter D50 (nm) was calculated for the nickel oxide nanoparticles dispersed in the aqueous solvent. A result of the calculation is shown in the table below.

TABLE 1

| | | | | |
|---|---|---|---|---|
| pH | 9 | 10 | 11 | 13 |
| crysallite size D (nm) | 4.5 | 4.4 | 4.2 | 3.5 |
| Solution passes through 0.45-μm filter? | Yes | Yes | Yes | No |
| Median diameter D50 (nm) of | 12.4 | 10.8 | 11.8 | — |
| particles dispersed in solution | | | | |

A case where the crystallite size is smaller than 4 nm shows that, compared with a case where the crystallite size is 4 nm or more, the particles agglomerate together in a great degree when dispersed in the aqueous solvent. This is probably because organic ligands, which help the nickel oxide nanoparticles disperse, are not coordinated to the surface of the nickel oxide nanoparticles, and, when the particle size of the nickel oxide nanoparticles is excessively small, the nickel oxide nanoparticles nearby would act to agglomerate together and reduce the surface area. The agglomeration in a great degree extremely increases the roughness of the nickel oxide nanoparticle layer when applied, and causes decreases in the EQE because of an increase in reactive current of the light-emitting element and in reliability because of current concentration. Hence, the nickel oxide nanoparticles to which no organic ligands are coordinated have a particle size (e.g.,) of preferably 4 nm or more.

In this example, the aqueous sodium hydroxide was added to the solution, such that the solution had a pH of 10. Obtained as a result was the nickel oxide nanoparticles, and the nickel oxide nanoparticles were dispersed in a solution in which water and 2-methoxyethanol were mixed together at a volume ratio of 1:1. Hence, 15 mg/mL of nickel oxide nanoparticle solution (a nanoparticle dispersion) was prepared.

### Preparing Light-Emitting Element

On the substrate (e.g., the pixel circuit substrate), an ITO film (e.g., a thickness of 30 nm) is deposited by sputtering to form the anode. Next, under the atmosphere, the nickel oxide nanoparticle solution (the nanoparticle dispersion) was repeatedly applied (e.g., by spin coating) and heated (e.g., at 150 to 200° C.) once, twice, three times, four times, and five times depending on a desired thickness. Hence, nickel oxide nanoparticle layers (the light-scattering layers SL) were formed to have the respective thicknesses (maximum thicknesses Dt) of 31 nm, 36 nm, 47 nm, 54 nm, and 62 nm. Next, under an N₂ atmosphere, a chlorobenzene solution of poly-4-butyl-N,N-diphenylaniline (poly-TPD) was applied (e.g., by spin coating), and the solvent (chlorobenzene) was evaporated. Hence, a poly-TPD film (the hole transport layer YL) was formed to have a thickness of, for example, 30 nm. Next, under the N₂ atmosphere, light-emitting quantum dots (e.g., phosphor particles of InP emitting a red light) were dispersed in an octane solvent to prepare a solution. Then, the solution was applied by spin coating to form a quantum-dot layer (the light-emitting layer EM) having a thickness of, for example, 13 nm. Next, under the N₂ atmosphere, nanoparticles (e.g., a particle size of 5 nm) of a magnesium-zinc oxide (e.g., Mg_{0.15}Zn_{0.85}O) were dispersed in an ethanol solvent to prepare a solution. The solution was applied by spin coating to form an electron transport layer (the second functional layer SK) having a thickness of, for example, 60 nm. Next, an Ag film (the cathode EC) was formed by vacuum evaporation to have a thickness of, for example, 65 nm. Next, under the N₂ atmosphere, the substrate and the light-emitting element on the substrate were sealed with a sealing member. The technique of applying the nickel oxide nanoparticle solution shall not be limited to spin coating. The technique may be inkjet printing.

Between the light-scattering layer SL and the hole transport layer YL, a self-assembled monolayer (SAM) may be formed. The self-assembled monolayer can be formed as follows. For example, [2-(3,6-dimethoxy-9H-methyl-9-yl)ethyl] phosphonic acid (MeO-2PACz) is dispersed in an ethanol solvent to prepare a solution. The solution is applied (to the light-scattering layer) and baked so that the solvent is evaporated. As a result, the self-assembled monolayer is formed. Here, a plurality of self-assembled monolayer is arranged along the asperities of the surface of the light-scattering layer SL.

The anode EA is formed of, other than indium tin oxide (ITO), indium zinc oxide (IZO), tin oxide (SnO₂), and fluorine-doped tin oxide (FTO), for example. The electron transport layer may be formed of, other than non-doped zinc oxide (ZnO), zinc oxide (ZnO) doped with at least one of Li, Al, Ti, Ga, or Zr, titanium oxide (TiO₂), and zirconium oxide (ZrO₂), for example. The hole transport layer is formed of, for example, TFB and PVK.

The nickel oxide nanoparticle solution (the nanoparticle dispersion) according to this example may contain 10% or more of water in volume proportion, and have a surface tension of 15 mN/m to 45 mN/m at 20° C. The nickel oxide nanoparticle solution contains highly polar water. That is why the nickel oxide nanoparticles are dispersed with no organic ligands coordinated. Because 2-methoxyethanol is mixed together, the solution has a surface tension of 45 mN/m or less, thereby improving in wettability to the substrate. Hence, when the solution is applied, the upper surface roughness does not extremely increase. Such a feature makes it possible to form roughness suitable for a hole-transporting light-scattering layer positioned below the light-emitting layer. The nickel oxide nanoparticle solution has a viscosity of 4 mPa·s or more at 20° C. Here, the surface tension of the nickel oxide nanoparticle solution is not as high as that of water. Hence, the nickel oxide nanoparticle solution can be ejected by inkjet printing.

The nickel oxide nanoparticle solution preferably omits organic ligands. The fact that the nickel oxide nanoparticle solution omits organic ligands can be checked by such a technique as the Fourier transform infrared spectroscopy (FTIR). For example, the nickel oxide nanoparticle solution is measured by the FTIR. If a peak supposed to be found between 2800 ^{cm-1} to 3000 ^{cm-1} is not observed because of C—H stretching, it can be understood that no organic ligands are contained.

The nickel oxide nanoparticle solution preferably contains nitrate ions. The nitrate ions promote dispersion of the nickel oxide nanoparticles in the solvent (water), so that the nanoparticles are less likely to agglomerate together. Such a feature improves stability of the solution. Hence, when the solution is applied and the upper surface roughness is formed, the upper surface roughness does not extremely increase. Nitric acid has a boiling point of as low as 83° C. When the nickel oxide nanoparticle solution is applied, or when the applied nickel oxide nanoparticle solution is heated, the nitrate ions are evaporated and do not affect the characteristics of the light-emitting element. The fact that the nickel oxide nanoparticle solution contains the nitrate ions can be checked by such a technique as the FTIR. In order to prevent the nitrate ions from remaining, the applied solution is heated preferably at 100° C. or above, and, more preferably, at 150° C. or above.

The nickel oxide nanoparticle solution has a boiling point of preferably 150° C. or below. When the boiling point of the nickel oxide nanoparticle solution exceeds 150° C., the water responsible for dispersing the nickel oxide nanoparticles is volatilized first while the nickel oxide nanoparticle layer is forming. In the remaining solvent, the nickel oxide nanoparticles might agglomerate together in a great degree. When the boiling point is 150° C. or below, the water is kept from boiling first.

In this example, the nickel oxide nanoparticle solution is repeatedly applied and heated preferably twice or more, and, more preferably, three times or more as will be described later. If the solution is not applied multiple times, the light-scattering layer SL has a zero-thickness region. Hence, the holes are less likely to be injected. When the solution is applied multiple times, the light-scattering layer SL substantially has no zero-thickness regions. Hence, light-scattering layer SL improves in hole-transporting capability. Specifically, when the light-scattering layer SL is inspected for 500 nm or more in a direction perpendicular to the layer thickness direction, a value of a ratio of a total length of the zero-thickness region to the inspection length is preferably less than 0.02. Furthermore, when the solution is applied multiple times, no specific portions of the light-scattering layer SL are provided with significantly larger upper surface roughness than another portion. Instead, the light-scattering layer SL can be provided with more uniform upper surface roughness.

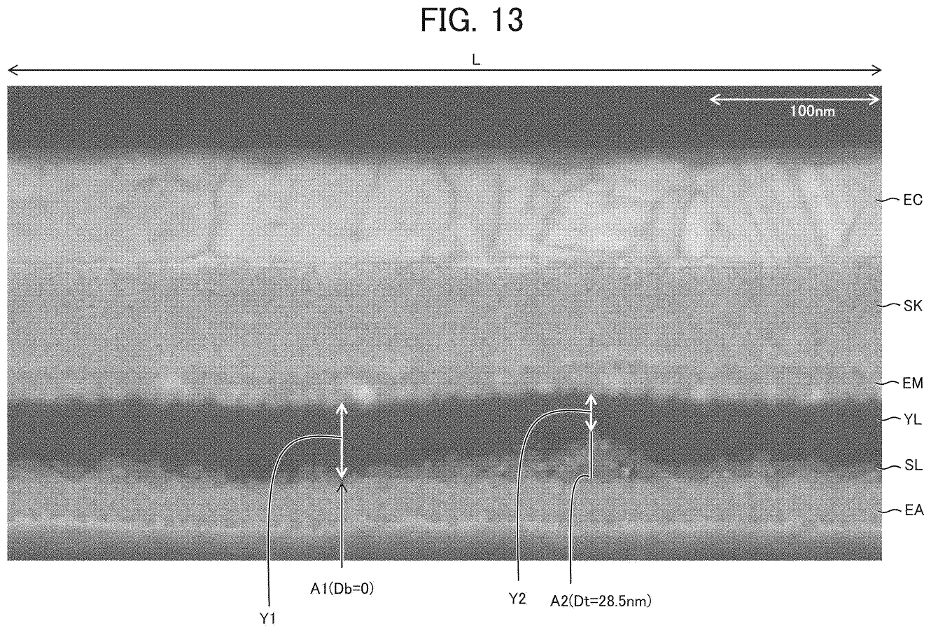

FIG. 13 is a cross-sectional SEM image of an example of a light-emitting element. In the light-emitting element in FIG. 13, the anode EA is formed of indium tin oxide (ITO), the light-scattering layer SL is formed of nickel oxide nanoparticles, the hole transport layer YL is formed of poly-TPD; that is, an organic material, the second functional layer (the electron transport layer) SK is formed of a magnesium-zinc oxide, and the cathode EC is formed of silver (Ag). The light-scattering layer SL in FIG. 13 is formed of a nickel oxide nanoparticle solution (a nanoparticle dispersion) applied once. The light-scattering layer SL has a position A1 in which no nickel oxide nanoparticles are found. The position A1 has a thickness (Db) of zero. The light-scattering layer SL has a maximum thickness (Dt) of 28.5 nm at a position A2, and an upper surface roughness of approximately 23.5 nm. The hole transport layer YL has a thickness Y1 of 46.8 nm above the position A1, and a thickness Y2 of 20.9 nm above the position A2. Hence, a sum of the thickness of the light-scattering layer SL and the thickness of the hole transport layer YL is 46.8 nm above the position A1, and 49.4 nm above the position A2. The upper surface roughness of the hole transport layer YL is 49.4-46.8=2.6 nm, approximately. As can be seen, the hole transport YL is smaller in upper surface roughness than the light-scattering layer SL. The hole transport layer YL is flatter than the light-scattering layer SL. Hence, even though the light-scattering layer SL has a large upper surface roughness, the light-emitting layer EM is flat across the region observed in FIG. 13 (the unit length L).

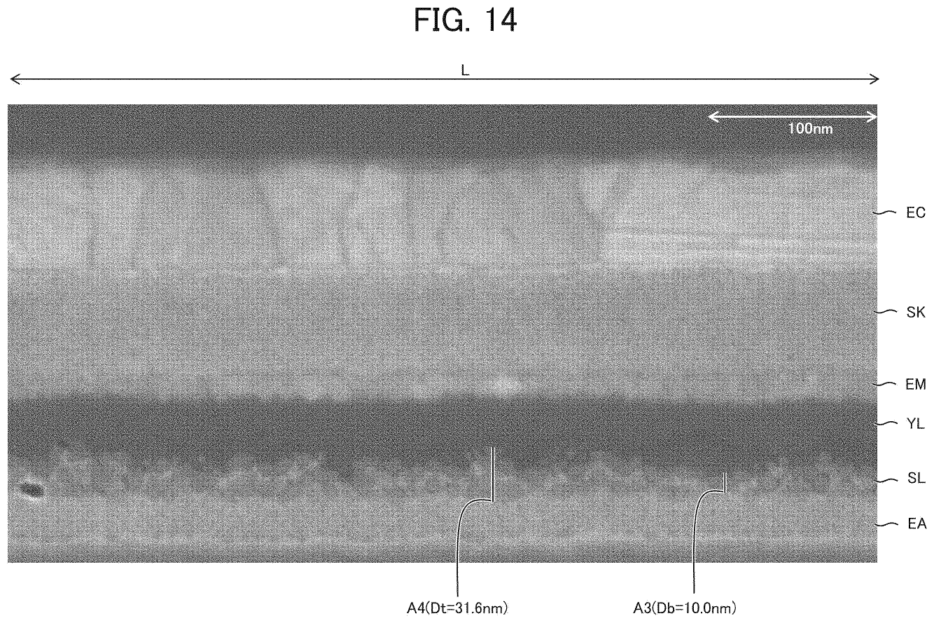

FIG. 14 is a cross-sectional SEM image of another example of the light-emitting element. The light-emitting element in FIG. 14 is formed of the same materials as those of the light-emitting element in FIG. 13. The light-scattering layer SL in FIG. 14 is formed of a nickel oxide nanoparticle solution applied twice. The light-scattering layer SL has a minimum thickness (Db) of 10.0 nm at a position A3. The light-scattering layer SL has a maximum thickness (Dt) of 31.6 nm at a position A4, and has an upper surface roughness of approximately 21.6 nm. In FIG. 14, the upper surface roughness of the hole transport layer YL (i.e., a difference between a sum of the thickness of the light-scattering layer SL and the thickness of the hole transport layer YL above the position A3 and a sum of the thickness of the light-scattering layer SL and the thickness of the hole transport layer YL above the position A4) is smaller than the upper surface roughness of the light-scattering layer SL. As can be seen, even though the light-scattering layer SL has a large upper surface roughness, the light-emitting layer EM is flat across the region observed in FIG. 14 (the unit length L) because of the hole transport layer YL.

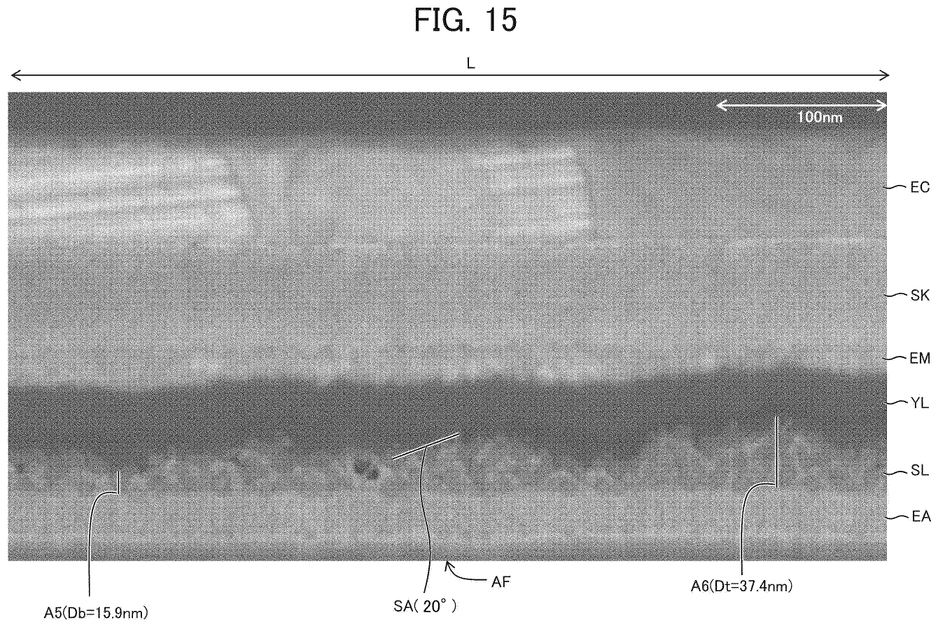

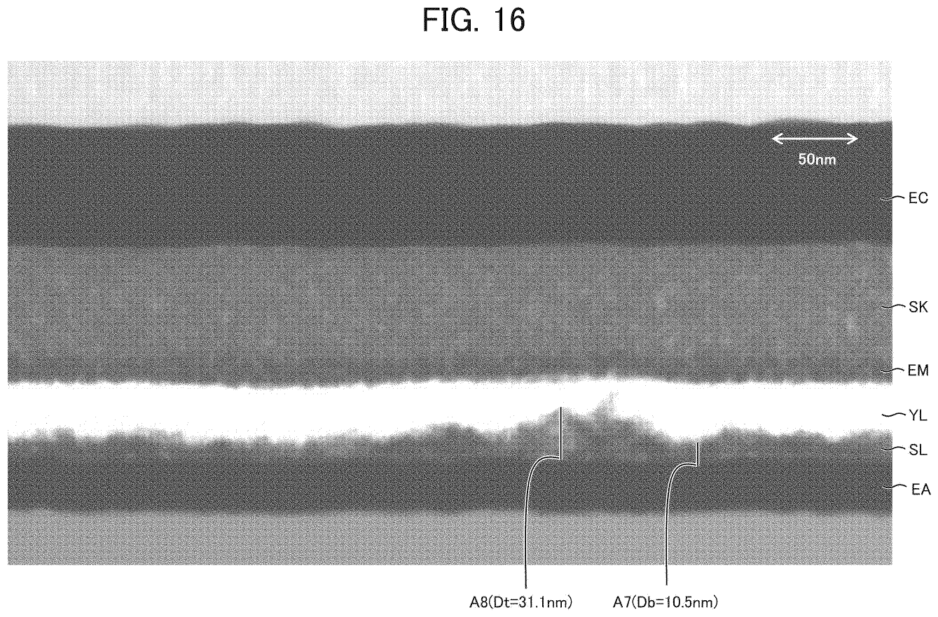

FIG. 15 is a cross-sectional SEM image of another example of the light-emitting element. The light-emitting element in FIG. 15 is formed of the same materials as those of the light-emitting element in FIG. 13. The light-scattering layer SL in FIG. 15 is formed of a nickel oxide nanoparticle solution applied three times. The light-scattering layer SL has a minimum thickness (Db) of 15.9 nm at a position A5. The light-scattering layer SL has a maximum thickness (Dt) of 37.4 nm at a position A6, and has an upper surface roughness of approximately 21.5 nm. In FIG. 15, the upper surface roughness of the hole transport layer YL (i.e., a difference between a sum of the thickness of the light-scattering layer SL and the thickness of the hole transport layer YL above the position A5 and a sum of the thickness of the light-scattering layer SL and the thickness of the hole transport layer YL above the position A6) is smaller than the upper surface roughness of the scattering layer SL. As can be seen, even though the light-scattering layer SL has a large upper surface roughness, the light-emitting layer EM is flat across the region observed in FIG. 15 (the unit length L) because of the hole transport layer YL. Furthermore, the light-scattering layer SL in FIG. 15 has an upper surface, and the upper surface has a region SA inclined with respect to the substrate surface AF at an angle of 20 degrees.

FIG. 16 is a STEM image of the light-emitting element in FIG. 13. In FIG. 16, the light-scattering layer SL has a minimum thickness (Db) of 10.5 nm at a position A7, and has a maximum thickness (Dt) of 31.1 nm at a position A8. The reason why the thicknesses of, for example, the light-scattering layer SL and the hole transport layer YL are measured larger in the STEM image of FIG. 16 than in the SEM image of FIG. 13 is because depth information is also observed with the STEM (unlike the SEM).

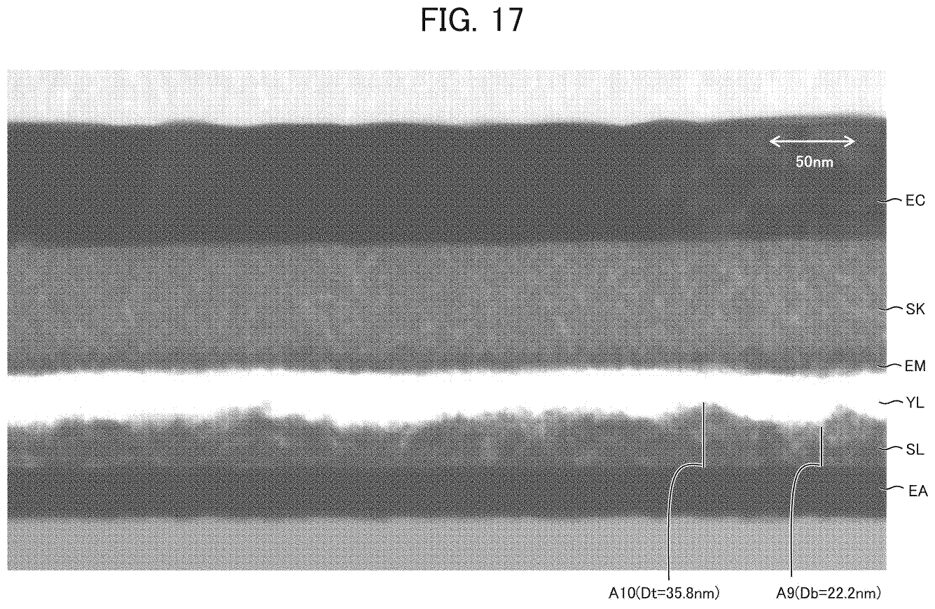

FIG. 17 is a STEM image of the light-emitting element in FIG. 14. In FIG. 17, the light-scattering layer SL has a minimum thickness (Db) of 22.2 nm at a position A9, and a maximum thickness (Dt) of 35.8 nm at a position A10.

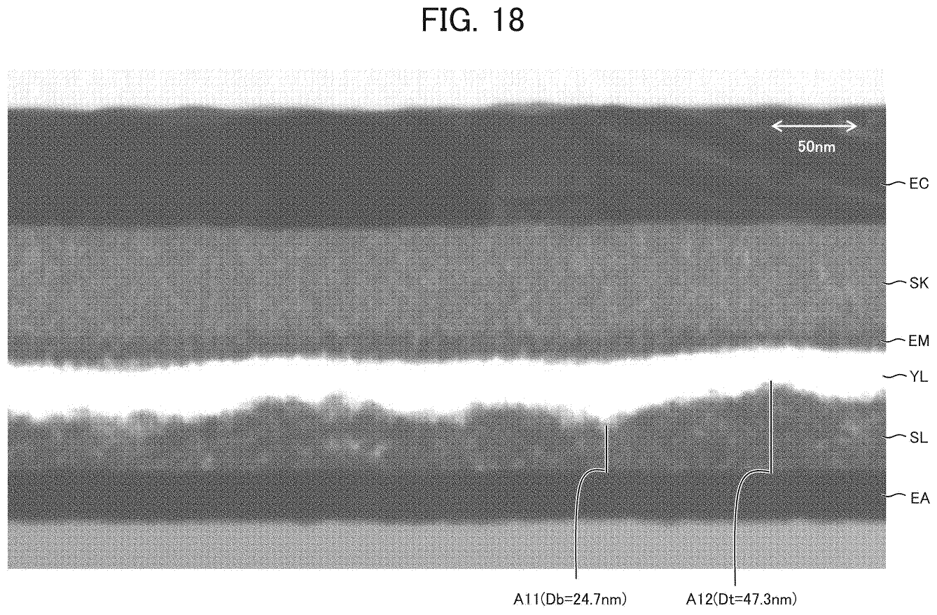

FIG. 18 is a STEM image of the light-emitting element in FIG. 15. In FIG. 18, the light-scattering layer SL has a minimum thickness (Db) of 24.7 nm at a position A11, and a maximum thickness (Dt) of 47.3 nm at a position A12.

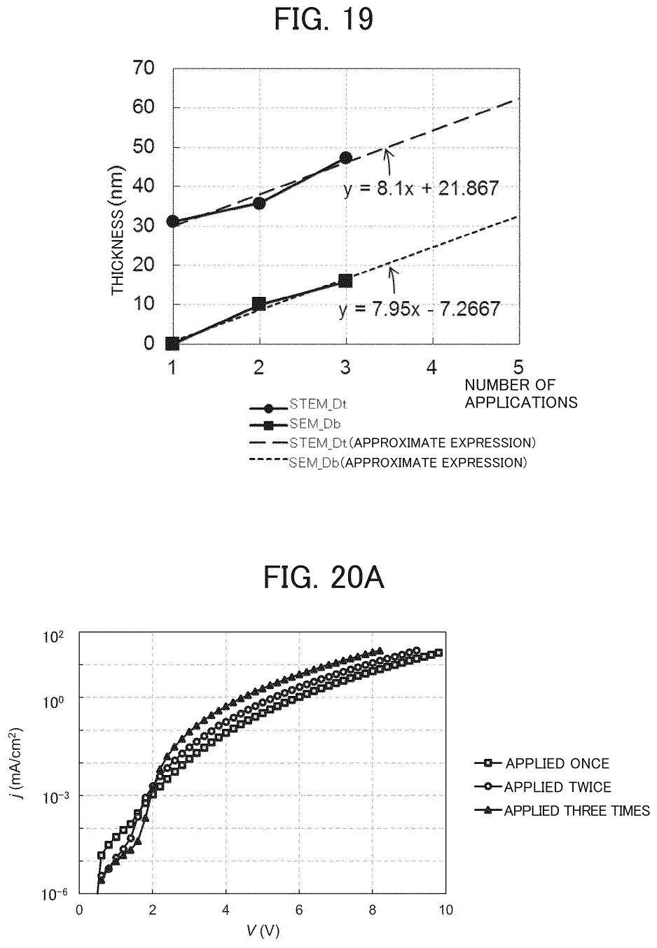

FIG. 19 is a graph illustrating a relationship between the number of applications and a thickness in forming the light-scattering layer. When a nanoparticle dispersion is applied once, twice, three times, four times, and five times, the light-scattering layer SL has a thickness of 31 nm, 36 nm, 47 nm, 54 nm, and 62 nm. The thickness is a thickness (Dt) of the thickest portion. If the nanoparticle dispersion is applied once to form the light-scattering layer SL, as illustrated in FIG. 13, FIG. 16, and FIG. 19, the light-scattering layer SL has a Db (i.e., a thickness of the thinnest portion in the base portion) of 0 nm and a Dt (i.e., a thickness of the thickest portion) of approximately 31 nm. Hence, the light-scattering layer SL has an upper surface roughness of 31 nm−0 nm=31 nm. A ratio of the thickness of the base portion BS to the upper surface roughness is 0%. In other words, here, the light-scattering layer has no base portion as illustrated in FIG. 9A.

If the nanoparticle dispersion is applied twice to form the light-scattering layer SL, as illustrated in FIG. 14, FIG. 17, and FIG. 19, the light-scattering layer SL has a Db (i.e., a thickness of the thinnest portion in the base portion) of approximately 10 nm and a Dt (i.e., a thickness of the thickest portion) of approximately 36 nm. Hence, the light-scattering layer SL has an upper surface roughness of 36 nm−10 nm=26 nm. A ratio of the thickness of the base portion BS to the upper surface roughness is 10/26=38%. Here, as to the light-scattering layer, the ratio of the thickness of the base portion BS to the upper surface roughness is small as illustrated in FIG. 9B.

If the nanoparticle dispersion is applied three times to form the light-scattering layer SL, as illustrated in FIG. 15, FIG. 18, and FIG. 19, the light-scattering layer SL has a Db (i.e., a thickness of the thinnest portion in the base portion) of approximately 16 nm and a Dt (i.e., a thickness of the thickest portion) of approximately 47 nm. Hence, the light-scattering layer SL has an upper surface roughness of 47 nm−16 nm=31 nm. A ratio of the thickness of the base portion BS to the upper surface roughness is 16/31=52%. Here, as to the light-scattering layer, the ratio of the thickness of the base portion BS to the upper surface roughness is sufficiently large as illustrated in FIG. 9C.

If the nanoparticle dispersion is applied four times to form the light-scattering layer SL, as illustrated in FIG. 19, the light-scattering layer SL has a Db (i.e., a thickness of the thinnest portion in the base portion) of approximately 25 nm and a Dt (i.e., a thickness of the thickest portion) of approximately 54 nm. Hence, the light-scattering layer SL has an upper surface roughness of 54 nm−25 nm=29 nm. A ratio of the thickness of the base portion BS to the upper surface roughness is 25/29=86%. Here, as to the light-scattering layer, the ratio of the thickness of the base portion BS to the upper surface roughness is sufficiently large as illustrated in FIG. 9C.

If the nanoparticle dispersion is applied five times to form the light-scattering layer SL, as illustrated in FIG. 19, the light-scattering layer SL has a Db (i.e., a thickness of the thinnest portion in the base portion) of approximately 32 nm and a Dt (i.e., a thickness of the thickest portion) of approximately 62 nm. Hence, the light-scattering layer SL has an upper surface roughness of 62 nm-32 nm=30 nm. A ratio of the thickness of the base portion BS to the upper surface roughness is 32/30=107%. Here, as to the light-scattering layer, the ratio of the thickness of the base portion BS to the upper surface roughness is sufficiently large as illustrated in FIG. 9C.

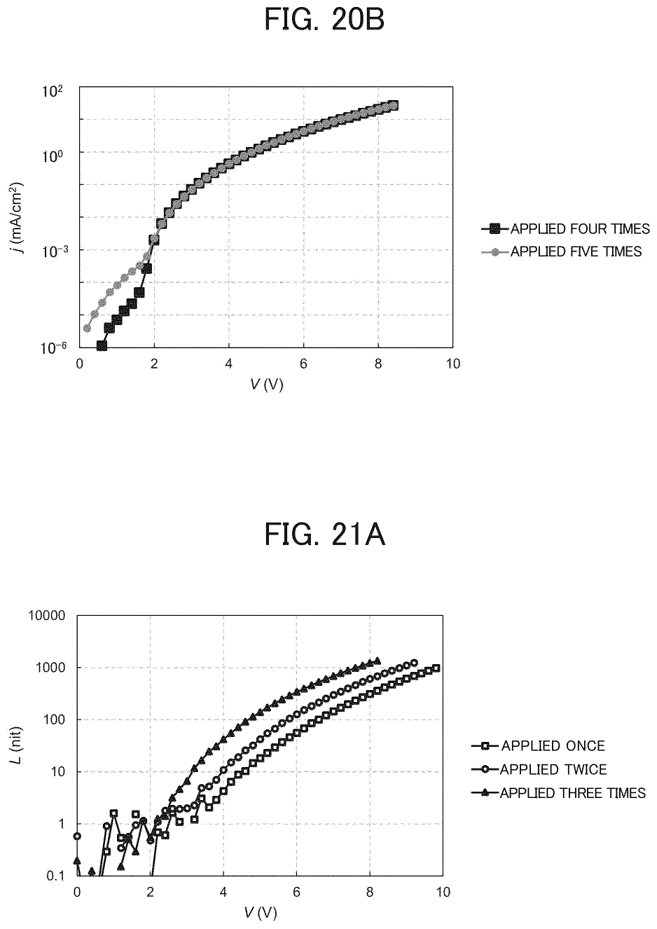

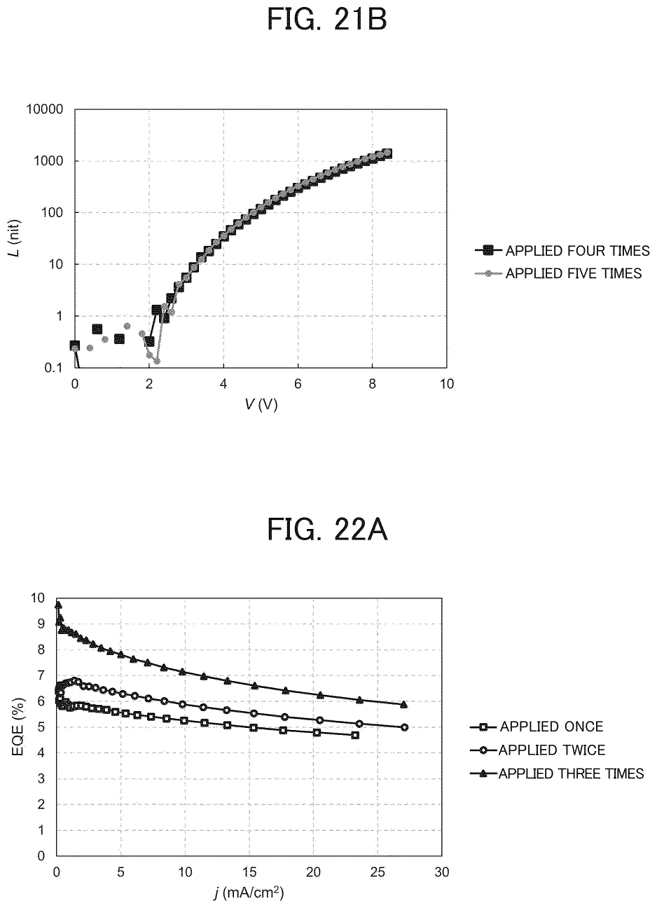

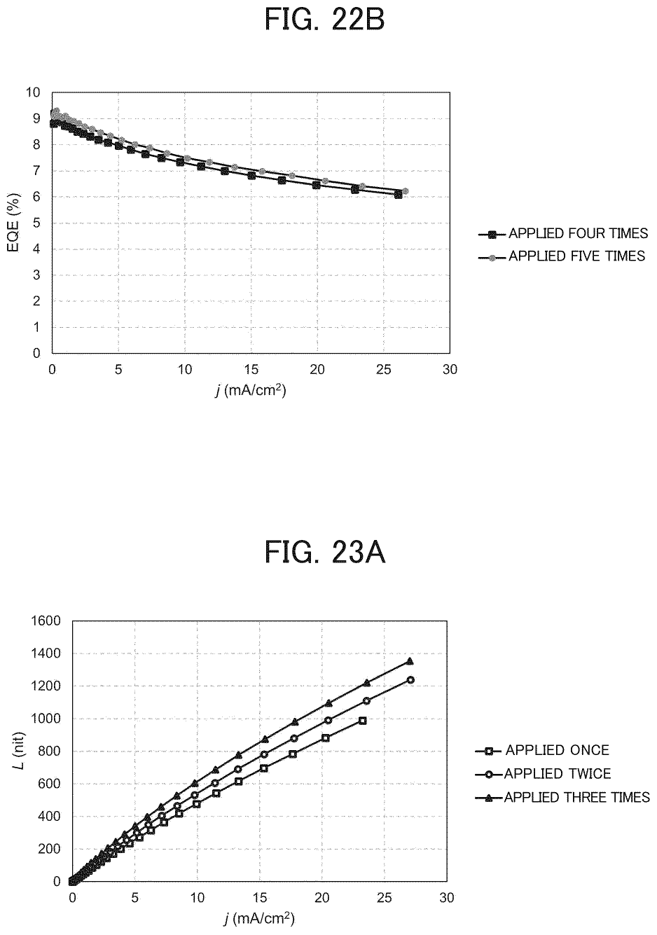

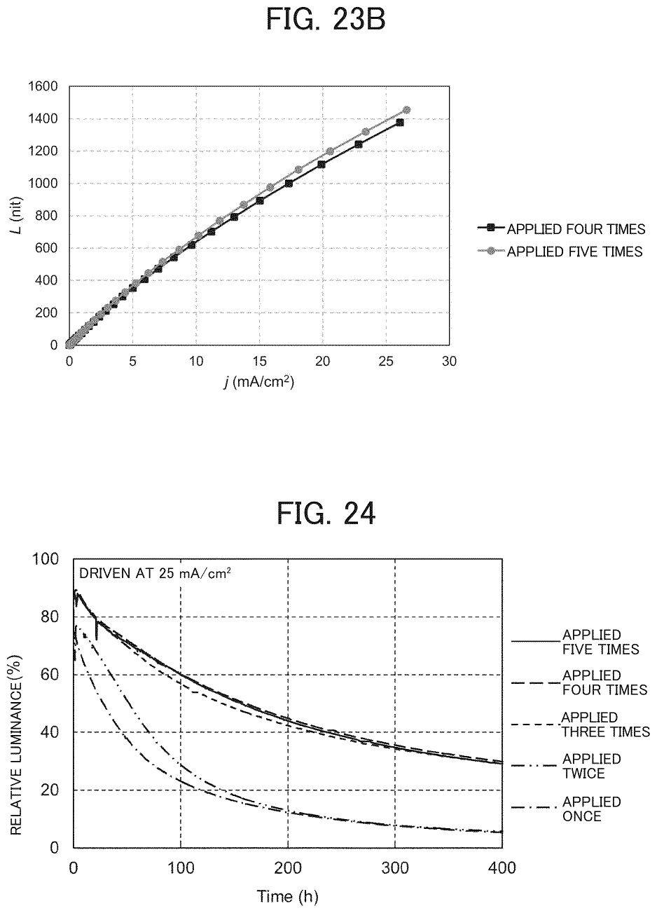

FIG. 20A and FIG. 20B show graphs illustrating voltage to current-density characteristics of the light-emitting element observed when the thickness (the number of applications) of the light-scattering layers varies. FIG. 21A and FIG. 21B show graphs illustrating voltage to luminance characteristics of the light-emitting element observed when the thickness (the number of applications) of the light-scattering layer varies. FIG. 22A and FIG. 22B show graphs illustrating current-density to EQE characteristics of the light-emitting element observed when the thickness (the number of applications) of the light-scattering layer varies. FIG. 23A and FIG. 23B show graphs illustrating current-density to luminance characteristics of the light-emitting element observed when the thickness (the number of applications) of the light-scattering layer varies. FIG. 24 is a graph illustrating time-related variations in relative luminance (reliability) of the light-emitting element observed when the thickness (the number of applications) of the light-scattering layer varies.

The graphs show that when the light-scattering layer SL (the nickel oxide nanoparticle layer) has a thickness (Dt) of 47 nm or more, both the EQE and the reliability significantly improve and the drive voltage falls. This is probably because, when the nickel oxide nanoparticle layer is thin, pores are formed in a portion of the nickel oxide nanoparticle layer because of the upper surface roughness, or the rate of variation in the layer thickness is large even if no pores are formed, which is a cause of decreases in hole injection capability and reliability. However, when the nickel oxide nanoparticle layer has a thickness of 47 nm or more, the pores disappear and the rate of variation in the layer thickness is sufficiently small, which is a cause of improvements in characteristics including the EQE and the reliability.

The EQE and the reliability of the light-emitting element significantly improve when the number of applications of the nickel oxide nanoparticle solution is changed from once to twice. That is, the base portion provided to the light-scattering layer SL significantly improves the EQE and the reliability. This is because, when no pores are formed, the hole injection capability and the carrier balance improve. The EQE and the reliability of the light-emitting element significantly improve when the number of applications of the nickel oxide nanoparticle solution is changed from twice to three times. That is, when the thickness of the base portion BS with respect to the upper surface roughness of the light-scattering layer SL varies from 38% to 52%, the EQE and the reliability significantly improve. Hence, significance of a critical range is found when the thickness (Db) of the base portion BS is 45% or more of the upper surface roughness (Dt-Db) of the light-scattering layer SL. This is because, in such a case, no pores are formed in the light-scattering layer SL (the nickel oxide nanoparticle layer) and the rate of variation in thickness of the layer is sufficiently small. As a result, adverse effects such as current concentration are less likely to occur.

As illustrated in FIG. 20A, when the nickel oxide nanoparticle solution is applied once to three times, the thickness of the light-scattering layer SL increases such that a voltage (required to obtain a predetermined current density) rather falls. When the solution is applied three times or more, the voltage is almost constant even if the light-scattering layer SL is formed thick (FIG. 20B). As illustrated in FIG. 22A, when the nickel oxide nanoparticle solution is applied once to three times, the thickness of the light-scattering layer SL increases such that the EQE of the light-emitting element improves. When the solution is applied three times or more, the EQE is almost constant even if the light-scattering layer SL is formed thick (FIG. 22B). As illustrated in FIG. 24, when the nickel oxide nanoparticle solution is applied once to three times, the thickness of the light-scattering layer SL increases such that the reliability of the light-emitting element improves. However, when the solution is applied three times or more, the reliability is almost constant even if the light-scattering layer SL is formed thick. Hence, the nickel oxide nanoparticle solution is repeatedly applied and heated preferably twice or more, and, more preferably, three times or more.

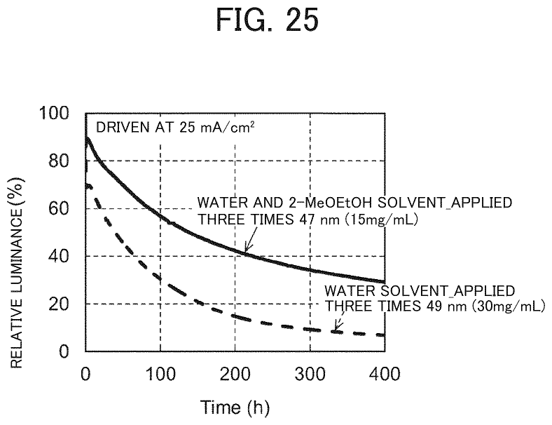

FIG. 25 is a graph illustrating time-related variations in relative luminance of the light-emitting element observed when a solvent of a nanoparticle dispersion is changed. In a case where a mixed solution of water and 2-MeOEtOH (2-methoxyethanol) is prepared as a solvent for a nanoparticle dispersion (having a concentration of 15 mg/mL), and the nanoparticle dispersion is applied three times to form a light-scattering layer having a thickness of 47 nm, the light-scattering layer exhibits a reduction in decrease of relative luminance caused by time-related variations, compared with a case where water alone is used as a solvent for a nanoparticle dispersion (having a concentration of 30 mg/mL), and the nanoparticle dispersion is applied three times to form a light-scattering layer having a thickness of 49 nm. As can be seen, the solvent of the nanoparticle dispersion is prepared of a mixed solution of water and an organic solvent, such that the reliability of the light-emitting element improves. This is probably because when the solution to be applied is mixed together with an organic solvent so as to have a surface tension of 45 mN/m or less, the solution improves in wettability to the substrate, the upper surface roughness does not extremely increase when the nickel oxide nanoparticle solution is applied, and the current concentration is less likely to occur.

Measuring apparatuses below were used for evaluation of the nickel oxide nanoparticles, the light-scattering layers, and the light-emitting elements.
X-ray diffraction (XRD) apparatus: MiniFlex II manufactured by Rigaku Corporation.
Particle size distribution measuring apparatus: Nanotrac wave II manufactured by MicrotracBell Inc.
Current-voltage characteristic measuring apparatus: 2400 manufactured by Keithley Instruments, LLC.
Luminance and spectrum measuring apparatus: MCPD7000 manufactured by Otsuka Electronics Co., Ltd.
Constant current life evaluation apparatus: EAS-10R manufactured by System Engineering Corp.

Each of the above-described embodiments is presented not for limitative purposes but for illustrative and descriptive purposes. It will be apparent to those skilled in the art that many variations are applicable in accordance with these illustrations and descriptions.

1. A light-emitting element, comprising:
an anode and a cathode;
a light-emitting layer positioned between the anode and the cathode; and
a light-scattering layer positioned between the light-emitting layer and the anode and containing metal oxide that transports holes.

2. The light-emitting element according to claim 1,
wherein the light-scattering layer has an upper surface roughness of 5 [nm] to 70 [nm].

3. The light-emitting element according to claim 1,
wherein the light-scattering layer includes: a base portion positioned toward the anode; and a light-scattering portion positioned toward the light-scattering layer.

4. The light-emitting element according to claim 3,
wherein the base portion has a thickness of 45 [%] or more of an upper surface roughness of the light-scattering layer.

5. The light-emitting element according to claim 1,
wherein the light-scattering layer contains carbon atoms of 0 to 5 [at %].

6. The light-emitting element according to claim 1,
wherein the light-scattering layer omits organic ligands.

7. The light-emitting element according to claim 1,
wherein an upper surface of the light-scattering layer is provided with a region having a slope forming an angle of 16 degrees or more and 43 degrees or less with respect to a plane in parallel with the anode.

8. The light-emitting element according to claim 1, further comprising
a hole transport layer positioned between the light-scattering layer and the light-emitting layer and containing an organic material.

9. The light-emitting element according to claim 8,
wherein an upper surface of the hole transport layer is smaller in roughness than an upper surface of the light-scattering layer.

10. The light-emitting element according to claim 8,
wherein the hole transport layer is lower in refractive index than the light-scattering layer.

11. The light-emitting element according to claim 8,
wherein the hole transport layer has a lower surface shaped in conformity with an upper surface of the light-scattering layer.

12. The light-emitting element according to claim 8,
wherein the hole transport layer has a thickness greater than an upper surface roughness of the light-scattering layer.

13. The light-emitting element according to claim 1,
wherein the metal oxide is any one of nickel oxide, copper oxide, vanadium oxide, molybdenum oxide, and tungsten oxide.

14. The light-emitting element according to claim 13,
wherein the metal oxide is nickel oxide, and
the light-scattering layer has a thickness of 47 [nm] or more.

15. The light-emitting element according to claim 1,
wherein the light-scattering layer has a polycrystalline structure.

16-18. (canceled)

19. The light-emitting element according to claim 1, further comprising
a substrate,
wherein the anode is closer to the substrate than the cathode.

20-22. (canceled)

23. The light-emitting element according to claim 1, further comprising
a hole transport layer positioned between the light-scattering layer and the light-emitting layer and containing an organic material, the light-scattering layer containing nickel oxide nanoparticles.

24-26. (canceled)

27. A light-emitting element, comprising:
an anode and a cathode;
a light-emitting layer positioned between the anode and the cathode, and containing quantum dots;
a nickel oxide nanoparticle layer positioned between the anode and the light-emitting layer, containing a nickel oxide nanoparticle group, and having an upper surface roughness larger than a particle size of nickel oxide nanoparticles in the nickel oxide nanoparticle group and smaller than 1/10 of an emission peak wavelength of the light-emitting layer; and
a hole transport layer positioned between the nickel oxide nanoparticle layer and the light-emitting layer, containing an organic material, and smaller in upper surface roughness than the nickel oxide nanoparticle layer.

28. A display device, comprising:
a first subpixel configured to emit a red light; a second subpixel configured to emit a green light; and a third subpixel configured to emit a blue light,
wherein each of the first subpixel, the second subpixel, and the third subpixel includes the light-emitting element according to claim 1.

29. (canceled)

30. A nanoparticle dispersion, comprising
a plurality of nanoparticles containing nickel oxide and dispersed in the nanoparticle dispersion, the nanoparticle dispersion containing 10% or more of water in volume proportion, and having a surface tension of 15 mN/m to 45 mN/m at 20° C.; and
at least one of 1,4-dioxane, 2-butanol, 1-butanol, pyridine, acetic acid, 2-methoxyethanol, or acetylacetone.

31-37. (canceled)
